(19) United States
(12) Patent Application Publication
(10) Pub. No.: US 2009/0085227 A1
(43) Pub. Date: Apr. 2, 2009

(54) FLIP-CHIP MOUNTING BODY AND FLIP-CHIP MOUNTING METHOD

(75) Inventors: Tsukasa Shiraishi, Osaka (JP); Seiichi Nakatani, Osaka (JP); Seiji Karashima, Osaka (JP); Koichi Hirano, Osaka (JP); Takashi Kitae, Osaka (JP); Yoshihisa Yamashita, Kyoto (JP); Takashi Ichiryu, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/914,581

(22) PCT Filed: May 9, 2006
(86) PCT No.: PCT/JP2006/309339

§ 371 Date: Nov. 16, 2007

(30) Foreign Application Priority Data
May 17, 2005 (JP) 2005-143745
May 18, 2005 (JP) 2005-144887

(51) Int. Cl. H01L 23/488; H01L 21/60

(52) U.S. Cl. 257/778; 438/106; 257/E21.511; 257/E23.023

(57) ABSTRACT

A flip chip mounting body in which a circuit substrate having a plurality of connection terminals and an electronic part (semiconductor chip) having a plurality of electrode terminals are aligned face to face with each other, with a resin composition composed of solder powder, a resin and a convection additive being sandwiched in between, while a means such as spacers is interposed in between so as to provide a uniform gap between the two parts, or the electronic part (semiconductor chip) is placed inside a plate-shaped member having two or more protruding portions, so that the solder powder is allowed to move through boiling of the convection additive and to be self-aggregated to form a solder layer, thereby electrically connecting the connection terminals and the electrode terminals; and a mounting method for such a mounting body.

### TECHNICAL FIELD

The present invention relates to a flip chip mounting method used for mounting a semiconductor chip and an electronic part on a circuit substrate, and in particular, concerns a flip chip mounting body and flip chip mounting method, which are also applicable to a semiconductor chip and an electronic part having narrowed pitches, have high productivity and are also superior in reliability upon connection.

### BACKGROUND ART

In recent years, there have been remarkable developments in providing high-function and multi-functional electronic apparatuses by achieving high-density and highly integrated semiconductor integrated circuit (hereinafter, referred to as “semiconductor” or “LSI”) chips to be used in the electronic apparatuses, and in response to these trends, with respect to the electrode terminals of a semiconductor chip, the number of pins has been increased and the pitches thereof have been further narrowed very rapidly. Upon mounting these semiconductor chips on a circuit substrate, a flip chip mounting process has been widely used so as to reduce the delay in wiring.

With respect to the method of mounting an LSI chip on a circuit substrate, two methods are mainly used, that is, a flip chip mounting method in which an LSI chip is directly mounted on a circuit substrate, and a method in which the mounting process is carried out after a semiconductor package has been once formed.

In general, in the mounting method for an LSI chip having a number of pins, with respect to the flip chip mounting technique, a mounting mode in which solder bumps, formed on pad electrode terminals of an LSI chip arranged in an area array state, are used for joining these to electrodes on a circuit substrate is proposed, and with respect to the package assembling technique, a mode in which an area array-type package with electrodes being arranged on the package rear face as an area array is assembled on a circuit substrate through solder balls is proposed, and these modes have been widely used for the production as highly reliable, superior techniques (for example, see Patent Document 1 or Patent Document 2).

However, in addition to an increased number of pins in an LSI chip, since the LSI chip size has been miniaturized as the wiring process rule is made finer, the pitch of pin intervals has been further narrowed very quickly. In the case of solder bumps formed on a conventional LSI chip electrode as well as in the case of a mounting mode that uses solder balls formed on the rear-face electrodes in an area array-type semiconductor package so as to carry out a joining process, it is necessary to miniaturize the size of the solder bumps and solder balls in response to the electrode size that is miniaturized in accordance with the narrowed pitches. This is because the use of solder bumps and solder balls having a large size causes fused solder to overflow the electrode pad, resulting in short-circuiting between adjacent pins. However, it is very difficult to uniformly form solder bumps and solder balls having a fine size, and further to join these onto a circuit substrate in a stable manner.

In the flip chip mounting, in general, solder bumps are formed on electrode terminals of a semiconductor chip, and the solder bumps and connection terminals formed on a circuit substrate are joined to each other at one time; however, in an attempt to assemble a semiconductor chip of the next generation having, for example, the number of electrode terminals exceeding 5000 on the circuit substrate, it is necessary to form solder bumps suitable for a narrow pitch of 100 μm or less. In the current solder bump forming technique, however, it is very difficult to meet this demand.

Since a large number of solder bumps corresponding to the number of electrode terminals have to be formed, there are also demands for achieving high productivity by shortening the mounting tact time per chip so as to reduce costs.

At present, in order to properly address an increase in the number of electrode terminals, the layout of electrode terminals of a semiconductor chip has been changed from a peripheral layout to an area layout.

Because of demands for high density, highly integrated devices, the semiconductor process is expected to be developed from 90 nm to 65 nm and further to 45 nm. In order to meet these demands, there have been strong demands for an insulating material having a low dielectric constant, and in an attempt to achieve this, porous insulating materials have been introduced.

However, in order to use the porous insulating material, a mounting process with a low load is required so as to reduce damages to the insulating material and the active circuit. In order to prevent breakages upon handling thin-type semiconductor chips, a mounting process with a low load is also required. In particular, in the case of an area layout, since electrodes have to be formed on an active circuit, a mounting method with a lower load is required.

For these reasons, there have been strong demands for a flip chip mounting method that is applicable to thin, high-density devices in response to future developments in the semiconductor process.

Conventionally, with respect to the technique for forming solder bumps, a plating method, a screen printing method and the like have been developed. However, although the plating method is suitable for narrowed pitches, it requires complicated processes and the like, resulting in a problem with productivity. Although the screen printing method is superior in productivity, it is not suitable for narrowed pitches because a mask is used.

Under these circumstances, recently, some techniques used for selectively forming solder bumps on electrode terminals of a semiconductor chip and a circuit substrate have been developed. These techniques are not only suitable for forming fine solder bumps, but also capable of forming solder bumps at one time; therefore, they are superior in productivity, and have drawn public attention as techniques that are suitably applied to a mounting process of a semiconductor chip of the next generation onto a circuit substrate.

One of these methods has processes in which a solder paste composed of a mixture of solder powder and a flux is solid-applied onto a circuit substrate having electrode terminals formed on its surface, and by heating the circuit substrate, the solder powder is fused so that solder bumps are selectively formed on the electrode terminals that have high wettability (for example, see Patent Document 3).

There is a technique referred to as “super solder method”. In this technique, a paste-state composition (chemical reaction deposition-type solder) mainly composed of a lead salt of an organic acid and metal tin is solid-applied onto a circuit substrate on which electrode terminals are formed, and by heating the circuit substrate, a substituting reaction of Pb and Sn is allowed to take place so that an alloy of Pb and Sn is selectively deposited on the electrode terminals on the circuit substrate (for example, see Patent Document 4).

In a conventional flip chip mounting process, after a semiconductor chip has been mounted on a circuit substrate bearing solder bumps formed thereon, another process used for injecting a resin referred to as “under fill” between the semiconductor chip and the circuit substrate is required in order to secure the semiconductor chip onto the circuit substrate. This process causes an increase in the number of processes and reduction in the yield.

For this reason, as a method used for simultaneously carrying out an electrical connection between the electrode terminals of the semiconductor chip and the connection terminals of the circuit substrate that are made face to face with each other and a fixation of the semiconductor chip onto the circuit substrate, a flip chip mounting technique using an anisotropic conductive material has been developed. This is a method in which: a thermosetting resin containing conductive particles is supplied between the circuit substrate and the semiconductor chip, and by heating the thermosetting resin simultaneously with pressing the semiconductor chip, the electrical connection and the fixation between the semiconductor chip and the circuit substrate are simultaneously achieved (for example, see Patent Document 5).

### Patent Document 1: Japanese Patent Application Laid-Open No. 11-163510

### Patent Document 2: Japanese Patent Application Laid-Open No. 11-067829

### Patent Document 3: Japanese Patent Application Laid-Open No. 2000-94179

### Patent Document 4: Japanese Patent Application Laid-Open No. 1-157796

### Patent Document 5: Japanese Patent Application Laid-Open No. 2000-332055

### DISCLOSURE OF INVENTION

### Problems to be Solved by the Invention

However, in the method of forming solder bumps shown in Patent Document 3 as well as in the super solder method shown in Patent Document 4, in the case when the paste-state composition is simply applied to a circuit substrate, local deviations in thickness and density occur to make amounts of solder deposition different depending on the respective connection terminals, failing to provide solder bumps having a uniform height. In these methods, since the paste-state composition is applied onto a circuit substrate on the surface of which connection terminals are formed and which consequently has irregularities, a sufficient amount of solder is not supplied onto the connection terminals forming convex portions, resulting in difficulty in providing a desired height of solder bumps required for the flip chip mounting.

In the flip chip mounting method shown in Patent Document 5, there are many problems in productivity and reliability to be solved, as shown below.

First, since electrical conduction is obtained between the electrode terminals by mechanical contact through conductive particles, it is difficult to achieve a stable conductive state. Second, since the gap is not constant due to different amounts of the conductive particles located between the semiconductor chip and the respective terminals of the circuit substrate, the electrical joining becomes unstable. Third, the heating process for curing the thermosetting resin causes the conductive particles to scatter, resulting in short-circuiting and reduction in yield. Fourth, due to the structure in which the semiconductor chip is exposed onto the circuit substrate, the semiconductor chip tends to have a defective connection caused by rubbing and impacts upon assembling the circuit substrate onto an apparatus, resulting in a failure. Fifth, in order to achieve a stable electrical connection, pressing and press-bonding processes by high pressure (load) are required, with the result that the semiconductor chip tends to be broken.

The present invention has been made so as to solve the above-mentioned problems, and its objective is to provide a flip chip mounting body and a flip chip mounting method, that are superior in productivity and reliability, and allow a semiconductor chip of the next generation, such as a chip having the number of electrode terminals exceeding 5000, to be mounted on a circuit substrate.

### Means to Solve the Problems

In other words, the present invention provides an electronic-part mounted product (first aspect of the invention), which is an electronic-part mounting body having an electronic part and a circuit substrate on which the electronic part is mounted, and has a structure in which the electronic part includes a plurality of electrode terminals formed on the surface of the electronic part that faces the circuit substrate; the circuit substrate is provided with electrode terminals formed thereon in association with the respective plurality of the electrode terminals; and a plurality of spacer members are placed on an area other than the electrode terminals of the connected circuit substrate and the electrode terminal portions of the electronic part, and in this structure, the electrode terminals of the circuit substrate and the electrode terminals of the electronic part are electrically connected to each other by solder bumps that are formed in a self-aggregating manner.

In a preferable embodiment, the height of the spacers is determined by setting the height of the solder bumps to not more than a height obtained by adding a half of the length of the shortest side in the electrode terminals of the electronic part and a half of the length of the shortest side in the electrode terminals of the circuit substrate.

In another preferable embodiment, the spacer members are formed of a solder material.

In still another preferable embodiment, the spacer members are formed of a thermosetting resin material.

In still another preferable embodiment, the spacer members are formed of a photo-curable resin material.

In still another preferable embodiment, the spacer members are formed of a thermoplastic resin material.

In still another preferable embodiment, the spacer members are formed of a hot-melt-type resin material.

In still another preferable embodiment, the spacer members have a structure in which a core member is coated with a resin material.

The electronic apparatus of the present invention is an electronic apparatus that is provided with the above-mentioned electronic-part mounting body.

A method of manufacturing the electronic-part mounting body of the present invention includes: (a) preparing an electronic part having a surface on which electrode terminals are arranged; (b) preparing a circuit substrate having a surface on which electrode terminals, arranged in association with the electrode terminals of the electronic part; (c) forming a plurality of spacers at an area other than the electronic terminal portion on the surface bearing the electrode terminals, on at least either one of the electronic part and the circuit substrate; (d) applying a solder resin paste, composed of a resin as well as solder powder and a convection additive that is allowed to boil upon heating the resin contained in the resin, to the circuit substrate; (e) placing the electronic part on the circuit substrate with the solder resin paste being sandwiched in between; and (D) heating the solder resin paste to allow the convection additive to boil so that by the resin, the electrode terminals possessed by the electronic part and electrode terminals formed on the circuit substrate in association with the electrode terminals are electrically connected, and in this method, a predetermined gap is formed between the electrode terminals arranged on the electronic part and the electrode terminals arranged on the circuit substrate face in association therewith, by the spacers prepared in the above-mentioned step.

Another method of manufacturing the electronic-part mounting body of the present invention includes the steps of: (a) preparing an electronic part having a surface on which electrode terminals are arranged; (b) preparing a circuit substrate having a surface on which electrode terminals, arranged in association with the electrode terminals of the electronic part; (c) forming a plurality of spacers at an area other than the electronic terminal portion on the surface bearing the electrode terminals, on at least either one of the electronic part and the circuit substrate; (d) arranging the electronic part on the circuit substrate; (e) injecting a solder resin paste, composed of a resin as well as solder powder and a convection additive that is allowed to boil upon heating the resin contained in the resin, into a space formed between the electronic part and the circuit substrate; and (f) heating the solder resin paste to allow the convection additive to boil so that by the resin, the electrode terminals possessed by the electronic part and electrode terminals formed on the circuit substrate in association with the electrode terminals are electrically connected, and in this method, a predetermined gap is formed between the electrode terminals arranged on the electronic part and electrode terminals arranged on the circuit substrate face in association with the above-mentioned terminals, by the spacers prepared in the above-mentioned step.

In still another manufacturing method of the present invention that relates to the above-mentioned manufacturing method of the present invention, the electronic part is bonded to and maintained on the circuit substrate by using the spacers, in the step of arranging the electronic part on the circuit substrate.

The present invention provides a flip chip mounting body (second aspect of the invention) including a circuit substrate having a plurality of connection terminals; a semiconductor chip having a plurality of electrode terminals that are placed face to face with the connection terminals; and a plate-shaped member in which the semiconductor chip is positioned on the inner side thereof and bonded thereto, and which has at least two protruding portions placed on end portions thereof, and in this structure, the connection terminals of the circuit substrate and the electrode terminals of the semiconductor chip are electrically connected to each other by using a solder layer, with at least the circuit substrate and the semiconductor chip being fixed by a resin.

An electrode may be formed in a manner so as to surround the connection terminals of the circuit substrate, with a pseudbump being formed on the electrodes.

The electrodes may be formed in a scattered manner.

At least the tip of each protruding portion of the plate-shaped member may be made of metal or a resin coated with metal, and have wettability to solder.

The circuit substrate and the protruding portions of the plate-shaped member may be joined to each other through press bonding or ultrasonic wave joining.

The circuit substrate and the plate-shaped member may be joined to each other by the resin of a resin composition.

With these arrangements, the gap between the electrode terminals of the circuit substrate and the electrodes of the semiconductor chip can be made constant by using the protruding portions; therefore, it is possible to carry out a connecting process uniformly. Since the semiconductor chip is not exposed onto the circuit substrate, it is possible to achieve a flip chip mounting body that is less vulnerable to a failure such as a defective connection due to impacts and rubbing upon transportation, and superior in reliability.

A flip chip mounting method of the present invention places a semiconductor chip having a plurality of electrode terminals so as to face a circuit substrate having a plurality of connection terminals so that the connection terminals of the circuit substrate and the electrode terminals of the semiconductor chip are electrically connected to each other, and comprises:

positioning the semiconductor chip with respect to a plate-shaped member having at least two protruding portions placed on end portions thereof, and bonding the semiconductor chip thereto;

applying or adhering a resin composition mainly composed of solder powder, a convection additive and a resin to the circuit substrate or the semiconductor chip;

positioning the protruding portions of the plate-shaped member to which the semiconductor chip has been bonded so as to be placed on the circuit substrate, and securing the circuit substrate and the semiconductor chip to each other by the protruding portions with a specified gap;

heating the resin composition to a temperature at which the solder powder is fused so that a gas is generated through boiling or decomposition of the convection additive; and

allowing the fused solder powder to flow in the resin composition, during a process in which the gas is allowed to flow and discharged between the protruding portions of the plate member, and to be self-aggregated and allowed to grow so that the connection terminals and the electrode terminals are electrically connected to each other.

The resin composition may be made of a plate-shaped resin, a sheet-shaped resin or a paste-state resin, and may be allowed to adhere to the circuit substrate or the semiconductor chip.

In the step of securing the protruding portions of the plate-shaped member to the circuit substrate, the protruding portions of the plate-shaped member may be secured on the circuit substrate through solder preliminarily formed on the circuit substrate.

In the step of securing the protruding portions of the plate-shaped member to the circuit substrate, the protruding portions of the plate-shaped member may be joined to the circuit substrate through press bonding or ultrasonic wave joining.

Since these methods make it possible to carry out a mounting process by using a low load, a thin semiconductor chip, a semiconductor chip that allows an area layout or the like, as well as an insulating material having a low dielectric constant, can be used. It becomes possible to achieve a flip chip mounting method that ensures the reliable connection between the semiconductor chip and the circuit substrate, and has high reliability. Since a uniform joined state between the electrode terminals and the connection terminals is achieved, it becomes possible to provide a high yield and also to improve the production efficiency.

The flip chip mounting body of the present invention includes: a circuit substrate having a plurality of connection terminals; a semiconductor chip having a plurality of electrode terminals that are placed face to face with the connection terminals; and a box-shaped member in which the semiconductor chip is positioned on the inner side thereof and bonded thereto, and which has a hole that allows ventilation, and is opened at least in one direction, and in this structure, the connection terminals of the circuit substrate and the electrode terminals of the semiconductor chip are electrically connected to each other by using a solder layer, with at least the circuit substrate and the semiconductor chip being secured to each other by a resin.

The box-shaped member may cover the semiconductor chip, and may be formed into a box shape with the peripheral edge sticking out to form a flange placed on the peripheral portion of the opening of the box-shaped member.

The hole that allows ventilation of the box-shaped member may be formed only on a side wall portion of the box-shaped member to which no semiconductor chip is bonded.

An electrode may be formed in a manner so as to surround the connection terminals of the circuit substrate, with pseudbumps being formed on the electrode.

The electrodes may be formed in a scattered manner.

The box-shaped member may be made of metal or resin coated with metal, and have wettability to solder.

The circuit substrate and the box-shaped member may be joined to each other through press bonding or ultrasonic wave joining.

The circuit substrate and the box-shaped member may be joined to each other by the resin of the resin composition.

With these arrangements, the gap between the electrode terminals of the circuit substrate and the electrodes of the semiconductor chip can be made constant by using the side walls of the box-shaped member; therefore, it is possible to carry out a connecting process uniformly, and also to reduce warping of the circuit substrate. Since the semiconductor chip is not exposed onto the circuit substrate, it is possible to achieve a flip chip mounting body that is less vulnerable to a failure such as a defective connection due to impacts and rubbing upon transportation, and superior in reliability.

The flip chip mounting method of the present invention, which places a semiconductor chip having a plurality of electrode terminals so as to face a circuit substrate having a plurality of connection terminals so that the connection terminals of the circuit substrate and the electrode terminals of the semiconductor chip are electrically connected to each other, includes: positioning the semiconductor chip inside a box-shaped member that has a hole that allows ventilation, and is opened at least in one direction, and bonding the semiconductor chip thereto; applying or adhering a resin composition mainly composed of solder powder, a convection additive and a resin to the circuit substrate or the semiconductor chip; positioning the box-shaped member to which the semiconductor chip has been bonded so as to be placed on the circuit substrate, as well as securing the circuit substrate and the semiconductor chip to each other, with a specified gap, by the side edge portion on the opening side of the box-shaped member; heating the resin composition to a temperature at which the solder powder is fused so that a gas is generated through boiling or decomposition of the convection additive; and allowing the fused solder powder to flow in the resin composition, during a process in which the gas is allowed to flow and discharged through the hole of the box-shaped member, and to be self-aggregated and allowed to grow so that the connection terminals and the electrode terminals are electrically connected to each other.

The resin composition may be made of a plate-shaped resin, a sheet-shaped resin or a paste-state resin, and may be allowed to adhere to the circuit substrate or the semiconductor chip.

In the step of securing the side edge portion on the opening side of the box-shaped member to the circuit substrate, the side edge portion thereof may be secured on the circuit substrate through solder preliminarily formed on the circuit substrate.

In the step of securing the side edge portion on the opening side of the box-shaped member to the circuit substrate, the box-shaped member may be joined to the circuit substrate through press bonding or ultrasonic wave joining.

In the step of securing the side edge portion on the opening side of the box-shaped member to the circuit substrate, with the resin composition being interposed between the circuit substrate and the semiconductor chip, the box-shaped member may be pressed until the side edge portion on the opening side of the box-shaped member has been made in contact with the circuit substrate.

Since these methods make it possible to carry out a mounting process by using a low load, a thin semiconductor chip, a semiconductor chip that allows an area layout or the like, as well as an insulating material having a low dielectric constant, can be used. It becomes possible to achieve a flip chip mounting method that ensures the reliable connection between the semiconductor chip and the circuit substrate, and has high reliability. Since a uniform joined state between the electrode terminals and the connection terminals is achieved, it becomes possible to provide a high yield and also to improve the production efficiency.

### EFFECTS OF THE INVENTION

In accordance with the present invention, an electronic-part mounting body, which has an electronic part and a circuit substrate on which the electronic part is mounted, has a structure in which: the electronic part includes a plurality of electrode terminals formed on the surface of the electronic part that faces the circuit substrate; the circuit substrate is provided with electrode terminals formed thereon in association with the respective plurality of the electrode terminals; and a plurality of spacer members are placed on an area other than the electrode terminals of the connected circuit substrate and the electrode terminal portions of the electronic part, and in this structure, the electrode terminals of the circuit substrate and the electrode terminals of the electronic part are electrically connected to each other by solder bumps that are formed in a self-aggregating manner. Therefore, the gap distance between the electrodes of the electronic part to be mounted and the electrodes of the corresponding circuit board is easily set to a distance that is suitable for the formation of solder bumps that are formed in a self-aggregating manner so as to connect the gap at one time with high precision. Consequently, it becomes possible to achieve an electronic-part mounting body that is superior in productivity and reliability.

In accordance with the flip chip mounting body and its mounting method of the present invention, it becomes possible to achieve a flip chip mounting method that ensures the reliable connection between the semiconductor chip and the circuit substrate, and since the semiconductor chip is not exposed onto the circuit substrate on which the semiconductor chip is mounted, it is possible to achieve a flip chip mounting body that is less vulnerable to a failure such as a defective connection due to impacts and rubbing upon transportation, and superior in reliability. Since a uniform joined state between the electrode terminals and the connection terminals is achieved, it becomes possible to provide a high yield and also to improve the production efficiency.

### BRIEF DESCRIPTION OF THE DRAWINGS

FIGS. 1(a) to 1(c) are schematic cross-sectional views each of which shows a mounting body formed in manufacturing processes of the electronic-part mounting body in which a solder bump forming technique is utilized.

FIGS. 2(a) to 2(e) are schematic cross-sectional views each of which shows a mounting body formed in manufacturing processes of the electronic-part mounting body in accordance with one embodiment of the present invention.

FIG. 3 is a flow chart that shows manufacturing processes of an electronic-part mounting body in accordance with one embodiment of the present invention.

FIGS. 4(a) to 4(e) are schematic cross-sectional views each of which shows a mounting body formed in manufacturing processes of the electronic-part mounting body in accordance with another embodiment of the present invention.

FIG. 5 is a flow chart that shows manufacturing processes of an electronic-part mounting body in accordance with another embodiment of the present invention.

FIG. 6 is a drawing that shows a preferable gap distance between a rear face electrode and an electrode terminal of a circuit substrate of a semiconductor package in accordance with an embodiment of the present invention.

FIGS. 7(a) to 7(e) show schematic cross-sectional views each of which shows a mounting body formed in manufacturing processes of the electronic-part mounting body in accordance with another embodiment of the present invention.

FIG. 8(a) is a perspective view showing a flip chip mounting body in accordance with embodiment 1 of the present invention.

FIG. 8(b) is a cross-sectional view taken along line A-A of FIG. 2(a).

FIGS. 9(a) to 9(e) are schematic cross-sectional views of processes, which explain a flip chip mounting body and a flip chip mounting method in accordance with embodiment 1 of the present invention.

FIG. 10(a) is a perspective view that shows a plate-shaped member of FIG. 3(a) viewed diagonally from below.

FIG. 10(b) is a perspective view that shows a plate-shaped member of FIG. 3(b), viewed diagonally from below, to which a semiconductor chip has been attached.

FIG. 11(a) is a perspective view showing a flip chip mounting body in accordance with embodiment 2 of the present invention.

FIG. 11(b) is a cross-sectional view taken along line A-A of FIG. 5(a).

FIGS. 12(a) to 12(e) are schematic cross-sectional views of processes, which explain a flip chip mounting body and a flip chip mounting method in accordance with embodiment 2 of the present invention.

FIG. 13(a) is a perspective view that shows a box-shaped member of FIG. 6(a) viewed diagonally from below.

FIG. 13(b) is a perspective view that shows the box-shaped member of FIG. 6(b), viewed diagonally from below, to which a semiconductor chip has been attached.

### REFERENCE NUMERALS

10 Semiconductor package (electronic part)
11 Rear face electrode terminal
20 Spacer
21, 22 Joining pad
23 Core material
24 Resin material
30 Solder resin paste
31 Convection
40 Circuit substrate
41 Electrode terminal
50 Solder bump
100 Electronic-part mounting body
110 Circuit substrate
111 Connection terminal
112 Convection additive
113 Solder resin paste
121 Element electrode
122 Solder bump
201, 307, 401, 510 Circuit substrate
204, 308, 402, 511 Connection terminal
407 Resin
306 Resin composition
206, 304, 404, 507 Semiconductor chip
207, 305, 406, 508 Electrode terminal
208, 313, 405, 514 Solder layer
200, 400 Flip chip mounting body
202, 302 Protruding portion
203, 407, 509 Resin composition
205, 301 Plate-shaped member
209, 314 Pseudbump
210, 309 Electrode
403, 504 Box-shaped member
303 Vacuum suction device
310 Joining electrode
311, 512 Heater
312, 513 Gas
408, 506 Hole
409, 505 Flange
501 Transporting device
502 Hinge

### BEST MODE FOR CARRYING OUT THE INVENTION

The following description will discuss the first aspect of the invention.

The applicant of the present application has developed a unique technique which is capable of forming solder bumps or mounting flip chips by making solder self-aggregating under predetermined conditions, and disclosed the technique in the specification of Japanese Patent Application No. 2004-257206 as well as in the specification of Japanese Patent Application No. 2004-267919. The contents of the specification of Japanese Patent Application No. 2004-257206 and the specification of Japanese Patent Application No. 2004-267919 are incorporated by reference herein as one portion of the specification of the present application.

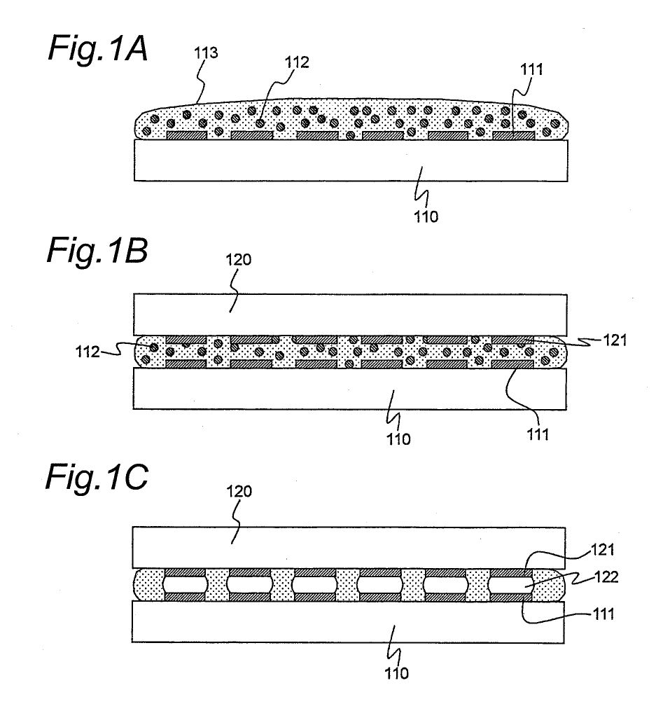

Referring to FIGS. 1(a) to 1(c), the following description will briefly discuss the technique of forming solder bumps by using the self-aggregating property.

First, as shown in FIG. 1(a), solder resin paste 113 containing metal particles (for example, solder powder), not shown, and a convection additive 112 is supplied onto a circuit substrate 110 where a plurality of connection terminals 111 are formed. Here, in the same manner as explained earlier, the convection additive 112 is an additive which boils when the solder resin paste 113 is heated to generate convections.

As shown in FIG. 1(b), a semiconductor chip 120 having a plurality of element electrodes 121 is made in contact with the surface of the solder resin paste 113. In this case, the element electrodes 121 of the semiconductor chip 120 are placed to face the connection terminals 111 of the circuit substrate 110. In this state, the solder resin paste 113 is heated. The heating temperature of the solder resin paste 113 is set to a temperature higher than the melting point of the metal particles and the boiling point of the convection additive 112.

The fused metal particles resulting from the heating process are joined with one another in the solder resin paste 113, and, as shown in FIG. 1(c), self-aggregated in a gap between the connection terminals 111 and the element electrodes 121, which have high wettability. Thus, a connecting member 122, which electrically connects the element electrodes 121 of the semiconductor chip 120 to the connection terminals 111 of the circuit substrate 110, is formed. Thereafter, the resin in the solder resin paste 113 is hardened so that semiconductor chip 120 is fixed to the circuit substrate 110.

The above-mentioned technique is characterized in that, when the solder resin paste 113 is heated, the convection additive 112, contained in the solder resin paste 113, boils, and the boiled convection additive 112 generates convections in the solder resin paste 113 so that the movements of metal particles dispersed in the solder resin paste 113 are accelerated. Thereby, the joining of the metal particles progresses uniformly so that the connecting members (solder bumps) 122 are formed in a self-aggregating manner. Here, it is considered that the solder resin paste 113 serves as “sea” which allows the metal particles to freely float and move therein; however, since the joining process of the mutual metal particles is completed in an extremely short period of time, even when “the sea” that allows the metal particles to freely move is prepared, the joining process is carried out only locally. Therefore, by combining the solder resin paste 113 forming “the sea” and the convections by the convection additive 112, the solder bumps 122 are formed in a self-aggregating manner. The solder bumps 122 are formed in the self-aggregating manner, and also simultaneously formed in a self-aligned manner as the inherent nature of the solder bumps.

The above-mentioned method is intended to add a means used for forcefully moving fused solder powder by allowing the resin composition containing the solder powder to further contain the convection additive. The convection additive may be a solvent that boils or evaporates upon heating, and is hardly left in the resin composition after the completion of the process.

In the above-mentioned technique, as shown in FIG. 1(b), it is necessary to form an appropriate constant gap distance between the element electrodes 121 of the semiconductor chip 120 and the connection terminals 111 of the circuit substrate 110 through the solder resin paste 113. In other words, in a connecting portion in which the gap between the semiconductor chip 120 and the circuit substrate 110 is too small to fail to provide a sufficient gap, the above-mentioned connecting members 122 are not formed; in contrast, in a connecting portion in which the gap is too wide to fail to provide contact to the resin, a problem arises in which no connecting members 122 are formed.

In order to solve the problem of failure in forming the connecting members, the inventors of the present invention have intensively studied the solder joining technique in which the self-aggregating property is utilized, and as a result, found a solution to the problem to complete the present invention.

Referring to Figures, the following description will discuss embodiments of the present invention. In the Figures, for convenience of explanation, those constituent parts having virtually the same functions are indicated by the same reference numerals. Here, the present invention is not intended to be limited by the following embodiments.

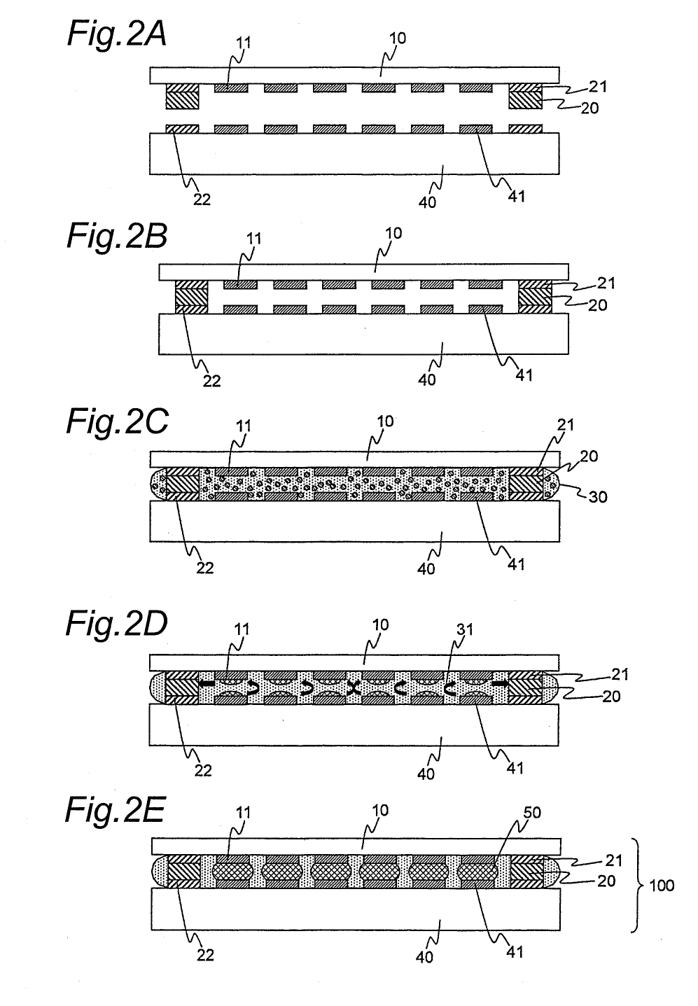

Referring to FIGS. 2(a) to 7(e), the following description will discuss an electronic-part mounting body 100 relating to an embodiment of the present invention and a manufacturing method thereof.

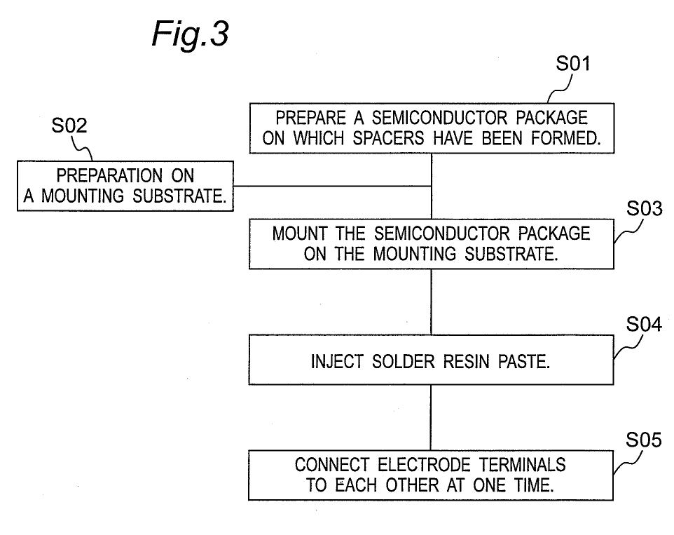

FIGS. 2(a) to 2(e) are schematic cross-sectional views showing the electronic-part mounting body in accordance with the present embodiment during main processes as well as upon completion, and FIG. 3 is a flow chart showing the mounting processes.

In FIG. 2(a), reference numeral 10 indicates a cross-sectional structure of a semiconductor package on which terminals in an area array, used for the electronic-part mounting body 100 of the present embodiment, are formed; reference numeral 11 indicates a rear-face electrode terminal in the area array; reference numeral 20 indicates a spacer made from a solder material having a high melting point; and 21 represents a joining pad to be joined with the spacer.

In FIG. 2(b), reference numeral 40 indicates a cross-sectional structure of a circuit substrate to be used for the electronic-part mounting body 100 of the present embodiment; reference numeral 41 indicates electrode terminals that are formed on the surface of the circuit substrate 40, and connected to each of the corresponding rear-face electrode terminals 11 formed on the semiconductor package 10; reference numeral 22 indicates joining pads to be joined with the spacers 20, formed on the surface of the circuit substrate 40. Reference numeral 30 indicates solder resin paste.

First, as shown in FIG. 2(a), the joining pad 21 and the spacer 20 formed thereon are prepared at predetermined positions of the semiconductor package 10 on one surface of which the rear-face electrode terminals 11 are formed (S01). A material for the joining pad 21 is required to allow a material such as solder to be used for the spacer 20 to be applied and joined thereto and held thereon. For example, it may have a structure in which gold (Au) 1 is plated on metal such as Cu, in the same manner as the rear-face electrodes of a generally-used semiconductor package. The spacer 20 is preferably made of a solder material having a high melting point that is higher than the melting temperature of the solder powder material contained in the solder resin paste 30, which will be described later. For example, the solder powder material contained in the solder resin paste 30 is prepared as PbSn eutectic solder (melting point: 183° C.), and the high-melting point solder material for the spacer 20 is prepared as SnAgCu-based material (melting point: 220° C.).

Separately, a circuit substrate 40, which has a desired wiring pattern (omitted in the Figure), and on one surface of which the electrode terminals 41 corresponding to the rear-face electrode terminals 11 of the semiconductor package 10 and the joining pads 22 joined to the spacers 20 are formed, is prepared (S02).

As shown in FIG. 2(b), the semiconductor package 10 is mounted at a predetermined position on the circuit substrate 40 through the spacers 20 (S03). At this time, the rear-face electrode terminals 11 formed on the semiconductor package 10 and the corresponding electrode terminals 41 formed on the circuit substrate 40 are spaced from each other with a predetermined gap.

After the mounting of the semiconductor package 10, as shown in FIG. 2(c), the solder resin paste 30 composed of a resin to which solder powder and a convection additive are added is poured and injected into the gap space of the semiconductor package 10 and the circuit substrate 40 (S40).

The convection additive, which boils when the resin is heated, is, for example, an organic solvent. When the solder resin paste 30 is heated, the convection additive in the solder resin paste 30 is allowed to boil, as shown in FIG. 2(d), to generate convections 31 in the resin. Then, as shown in FIG. 2(e), the solder powder in the solder resin paste 30 is self-aggregated so that each of solder bumps 50 is formed. The rear-face electrode terminals 11 of the semiconductor chip 10 and the electrode terminals 41 of the circuit substrate 40 are connected to each other at one time by the solder bumps 50 (S05).

In processes after the mounting process (S03) of the semiconductor package 10, a proper treatment, such as sandwiching the semiconductor package 10 and the circuit substrate, is required so as to prevent the semiconductor package 10 from separating from the circuit substrate 40.

In the present embodiment, a predetermined appropriate gap distance can be prepared easily with high precision between the rear-face electrode terminals 11 of the semiconductor package 10 and the corresponding electrode terminals 41 of the circuit substrate 40 so that it is possible to prevent the occurrence of a problem of a failure in forming the connecting bumps 50.

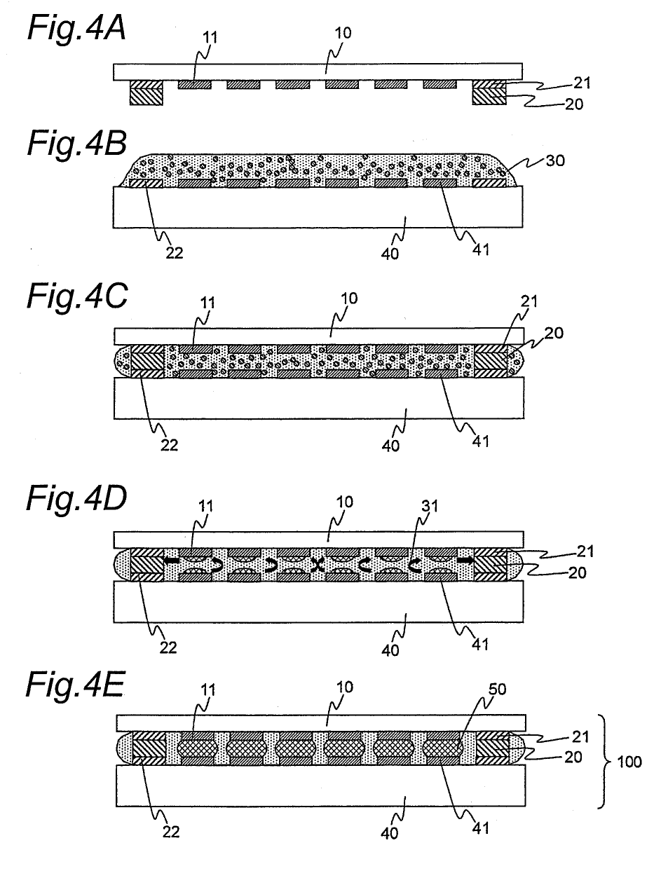

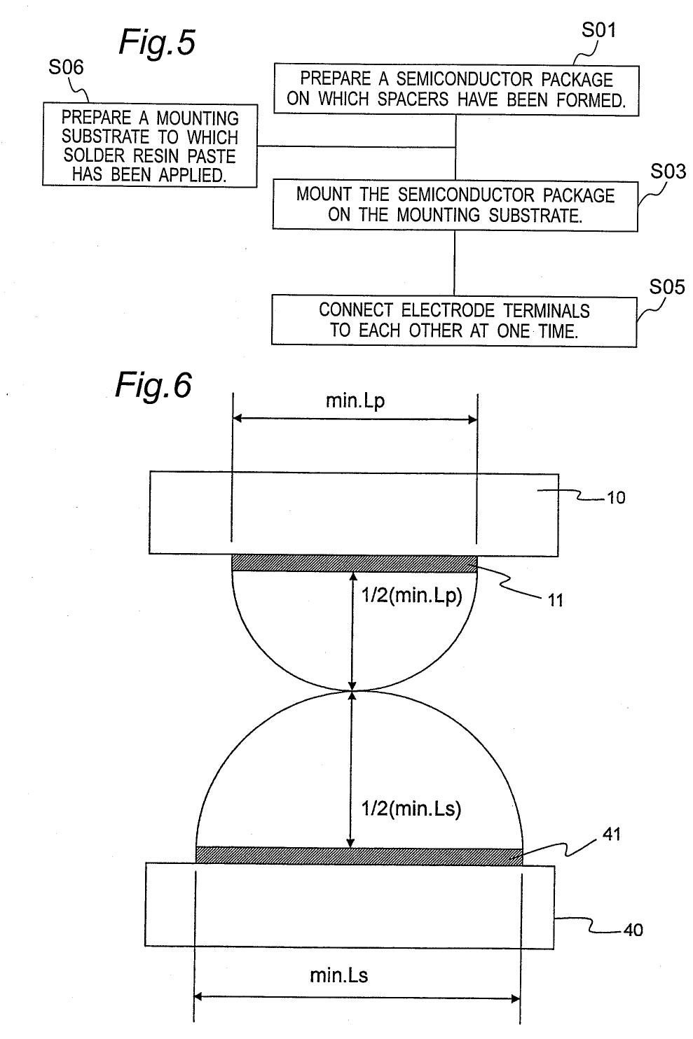

Referring to FIGS. 4(a) to 4(e) and FIG. 5, the following description will discuss a modified example of the manufacturing method of the present embodiment.

FIGS. 4(a) to 4(e) are schematic cross-sectional views which show electronic-part mounting bodies during main processes as well as upon completion in accordance with the modified example of the present embodiment. FIG. 5 is a flow chart that shows mounting processes thereof.

In the present embodiment, first, as shown in FIG. 4(a), a semiconductor package 10 having one surface on which the rear-face electrode terminals 11 are formed is prepared in such a manner that joining pads 21 with spacers 20 formed thereon are placed at predetermined positions (S01).

As shown in FIG. 4(b), a circuit substrate 40, which has a desired wiring pattern (omitted in the Figure), and on one surface of which the electrode terminals 41 corresponding to the rear-face electrode terminals 11 of the semiconductor package 10, the joining pads 22 which joins to the spacers 20 are formed, is prepared in such a manner that a desired amount of solder resin paste 30 is applied to a predetermined position on the surface thereof (S06).

As shown in FIG. 4(c), the semiconductor package 10 is mounted at a predetermined position on the circuit substrate 40 so as to be made in contact with the solder resin paste 30 through the spacers 20 (S03).

When the solder resin paste 30 is heated, the convection additive in the solder resin paste 30 is allowed to boil as shown in FIG. 4(d) so that convections 31 are generated in the resin. Then, as shown in FIG. 5(e), solder powder in the solder resin paste 30 is self-aggregated to form solder bumps 50. The rear-face electrode terminals 11 of the semiconductor chip 10 and the electrode terminals 41 of the circuit substrate 40 are connected to each other at one time by these solder bumps 50 (S05).

In processes after the mounting process (S03) of the semiconductor package 10, a proper treatment, such as sandwiching the semiconductor package 10 and the circuit substrate, is required so as to prevent the semiconductor package 10 from separating from the circuit substrate 40.

In this modified example of the present embodiment, by preliminarily applying the solder resin paste 30 onto the surface of the circuit substrate 40, the process (S04) used for pouring the solder resin paste 30 into the gap between the semiconductor package 10 and the circuit substrate 40 can be omitted. Therefore, since the solder resin paste 30 does not need a pouring property, a wider range of material selection is achieved.

In the above-mentioned embodiment, after the mounting process (S03) of the semiconductor package 10 onto the circuit substrate 40, the holding process through solder joining is carried out by using the spacer members 20 formed with solder so that it becomes possible to prevent the semiconductor package 10 from coming off the circuit substrate 40. Another process in which the semiconductor resin paste 30 is preliminarily applied onto the semiconductor package 10 side can, of course, provide the same effect.

In the above-mentioned embodiment, in order to form a gap with high precision, the number of the spacers 20 thus formed is preferably set to three or more. Thus, the tilt of the semiconductor package 10 mounted on the circuit substrate 40 is eliminated, and the precision of the gap distance is enhanced.

In the above-mentioned embodiment, with respect to the gap distance between the rear-face electrode terminals 11 of the semiconductor package 10 and the electrode terminals of the circuit substrate 40, supposing that the length of the shortest side in the rear-face electrode terminals 11 on the semiconductor package 10 side is min. Lp and that the length of the shortest side in the electrode terminals 41 on the circuit substrate 40 side is min. Ls, the maximum value of the gap distance is preferably set to half the sum of min. Lp and min. Ls. The reason for this arrangement is because, when the solder bumps 50, formed between the rear-face electrode terminals 11 of the semiconductor package 10 and the electrode terminals 41 of the circuit substrate 40, become larger than this distance, the solder tends to overflow the electrode terminals 11 and 41, causing a higher possibility of short-circuiting.

In the above-mentioned embodiment, the high-temperature solder material has been used as spacers 20; however, any of various other resin materials having a bonding properties, such as thermosetting resin, photo-curable resin, thermoplastic resin and hot-melt-type resin, may be used, and the same effects are also achieved.

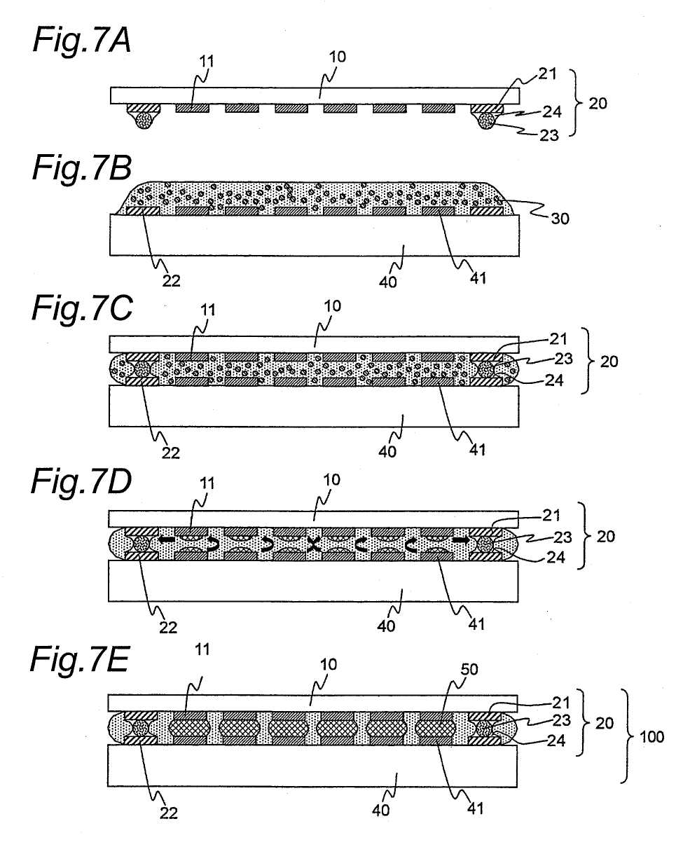

As shown in FIGS. 7(a) to 7(e), a composite structure, such as a bonding resin-coated core spacer in which, for example, a core material 23, made from a thermosetting resin that has been completely cured, is coated with a thermosetting resin material 24 in which an uncured portion having bonding properties remains, may be used.

Examples of the thermosetting resin include epoxy resin, phenol resin, cyanate resin, polyphenylene ether resin, and a mixture of these.

The photo-curable resin is a resin formed through a polymerization reaction caused upon irradiation with predetermined ultraviolet rays, and, for example, those of radical polymerization type include: acrylic oligomers, such as polyester acrylate, urethane acrylate and epoxy acrylate, unsaturated polyester and enthiol, or a compound of these may be used. Those of cation polymerization type include: glycidyl ether-based resins, epoxy-based resins such as alicyclic epoxy resins, or oxetane-based resins and vinyl ether-based resins, or a compound of these may be used.

Examples of the thermoplastic resin include polyethylene (PE), polypropylene (PP), polystyrene (PS), acrylonitrile/styrene resin (AS), acrylonitrile/butadiene/styrene resin (ABS), methacrylic resin (PMMA) and vinyl chloride (PVC).

Examples of the hot-melt-type resin material include: EVA (vinyl-acetate-based), PA (polyamide-based), PP (polypro-type) and rubber-based materials.

As described above, the solder resin paste 30 of the above-mentioned embodiment has a composition in which solder powder and a convection additive are contained in a resin so that the convection additive is allowed to boil when the resin is heated. In other words, the solder resin paste 30 is composed of a resin, solder powder (not shown) dispersed in the resin, and a convection additive (not shown) that is allowed to boil when the resin is heated. In the present embodiment, a thermosetting resin (for example, epoxy resin) is used as a resin, and Pb-free solder powder is used as a solder powder. With respect to the convection additive, a solvent (for example, a high-boiling point organic solvent) may be used, and, examples thereof include isopropyl alcohol, butyl acetate, butyl carbitol and ethylene glycol. The content of the solder powder is preferably set to 30 volume % or less. Although the content of the convection additive in the resin is not particularly limited, the convection additive is preferably contained in the resin at a rate from 0.1 to 20% by weight.

As described earlier, the “convection” of the convection additive refers to convection as a mode of movements, and any mode may be used as long as the boiled convection additive is allowed to move in the resin so that a kinetic energy is given to metal particles (solder powder) dispersed in the resin to accelerate the movement of the metal particles. Here, with respect to the convection additive, in addition to those additives that boil to generate convections, another convection additive which generates a gas (H₂O, CO₂, N₂ or the like) when the resin is heated may also be used, and examples of this type include a compound containing crystal water, a compound that is decomposed when heated and a foaming agent.

The formation time of the solder bumps 50 from FIGS. 2(b) to 2(c) as well as from FIGS. 4(d) to 4(e) is set to, for example, 5 to 30 seconds (typically, about 5 seconds), although different depending on conditions. Upon forming the solder bumps 50, a preheating process, which preliminarily heats the solder resin paste 30, may be introduced thereto.

The solder bumps 50 are formed in a self-aggregating manner, and also formed in a self-aligned manner with respect to the rear-face electrode terminals 11 and the electrode terminals 41. Therefore, virtually no positional deviations occur between the solder bumps and the rear-face electrode terminals 11 as well as the electrode terminals 41 so that the solder bumps are formed automatically in response to the patterns of the rear-face electrode terminals 11 and the electrode terminals 41.

The solder bumps 50 are formed with the solder powder in the solder resin paste 30 being self-aggregated; therefore, after the formation of the solder bumps 50, virtually no conductive particles are contained in the resin that has formed the solder resin paste 30, and the adjacent solder bumps 50 are insulated from each other by the resin forming the solder resin paste 30 as shown in FIGS. 2(e) and 4(e). The convection additive is formed into gases when heated, and discharged to outside and removed from the solder resin paste 30. After the formation of the solder bumps 50, the solder resin paste 30 is washed away, and another resin (or the same kind of resin) may be then injected.

After the resin forming the solder resin paste 30 (or another resin) has been cured, a mounting body 100 of the present embodiment shown in FIGS. 2(e) and 4(e) is obtained, and in the case when another resin is injected, with respect to the resin forming the solder resin paste 30, a resin other than the thermosetting resin (thermoplastic resin, photo-curable resin or the like) may be used.

Although the invention has been described with reference to preferred embodiments thereof, the invention is not intended to be limited by these descriptions, and, of course, various modifications can be made therein.

The LSI chip constituting the semiconductor package 10 is typically represented by a memory IC, a logic IC, or a system LSI, and the kind thereof is not particularly limited. The above-mentioned embodiments of the present invention have explained a structure in which the LSI chip is formed into the package 10; however, not limited to the semiconductor package, for example, the present invention may be used as a bear chip mounting means based upon a flip chip technique. The semiconductor package 10 may have a structure in which a semiconductor element such as a bear chip is formed into a module through an interposer (an intermediate substrate). This module is provided with a plurality of electrodes (mounting terminals), and examples of such a module include: an RF module and a power supply module. In addition to the module structure using the interposer, the semiconductor package 10 may be used as a component-integrated substrate module having a plurality of mounting terminals (for example, SIMPACT™).

The mounting body 100 in accordance with embodiments of the present invention is preferably mounted on a thin, small-size electronic apparatus in which the mounting area is limited. Not limited to cellular phones, it may be applied to PDAs and notebook-sized personal computers, and may also be applied to other applications (for example, digital still cameras and thin televisions of tapestry type (FPD: Flat Panel Display)).

The following description will discuss the second aspect of the present invention.

The applicant of the present application has proposed a novel flip chip mounting method of the next generation semiconductor chip (Japanese Patent Application No. 2004-267919). Based upon the above-mentioned Patent Application, the present invention provides a flip chip mounting method and a flip chip mounting body, which achieve superior effects.

From the same technical viewpoint as that of the flip chip mounting method explained in FIG. 1, the objective of the present invention is to achieve a novel flip chip mounting method that ensures high reliability. The method of the present invention makes it possible to manufacture flip chip mounting bodies with high productivity.

Referring to Figures, the following description will discuss embodiments of the present invention in detail. For convenience of explanation, the Figures are enlarged on demand.

### EMBODIMENT 1

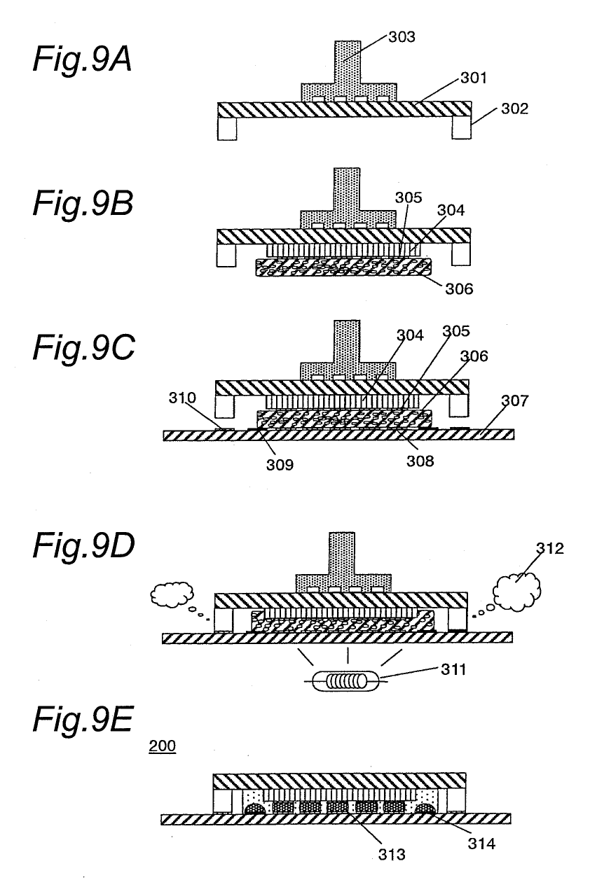

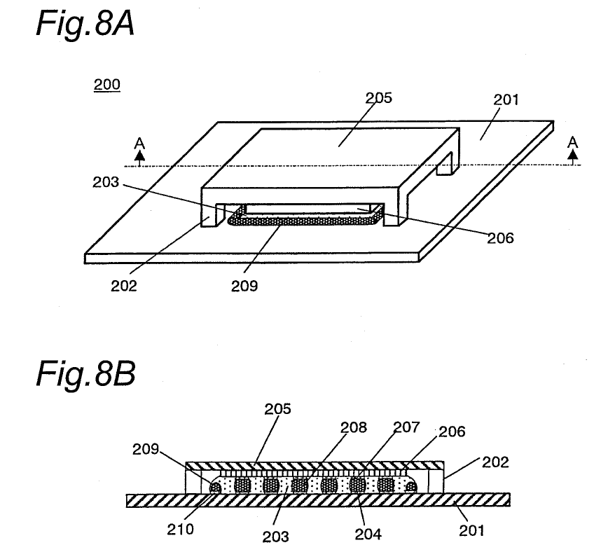

FIG. 8(a) is a perspective view that shows a flip chip mounting body in accordance with embodiment 1 of the present invention, and FIG. 8(b) is a cross-sectional view taken along line A-A of FIG. 8(a).

In FIG. 8, the flip chip mounting body 200 of embodiment 1 of the present invention has a structure in which a plurality of connection terminals 204 formed on a circuit substrate 201 and a plurality of electrode terminals 207 of a semiconductor chip 206, placed face to face with each other, are electrically connected to each other through a solder layer 208. A plate-shaped member 205, bonded to the side opposite to the formation face of the electrode terminals 207 of the semiconductor chip 206, is provided with four protruding portions 202 that are placed near its corner portions so as to cover the semiconductor chip 206. The four protruding portions 202 of the plate-shaped member 205 are directly joined to the circuit substrate 201 through, for example, press bonding or solder. With respect to the protruding portions 202, at least, in the case when they are joined to the circuit substrate 201 through solder, those protruding portions 202, made of metal or resin coated with metal, which exert superior wettability to solder, are used. In its space formed by the circuit substrate 201 and the plate-shaped member 205, at least the semiconductor chip 206 and the circuit substrate 201 are secured together with the solder layer 208 that electrically connects the connection terminals 204 to the electrode terminals 207, by the resin 203 that covers the peripheral portion thereof.

An electrode 210 is formed in a manner so as to surround the connection terminals 204 on the circuit substrate 201 to be joined to the electrode terminals 207 of the semiconductor chip 206, and pseudbumps 209 are formed thereon by solder powder that has been fused and aggregated. Since the solder powder is fused and aggregated onto the electrode 210 as pseudbumps 209 when heated and melted, so as to be captured thereon, no solder powder is scattered to the outside. With this arrangement, it is possible to prevent short-circuiting and the like due to solder powder that flows out of the plate-shaped member 205, and consequently to provide a flip chip mounting body 200 having high reliability.

In accordance with the flip chip mounting body 200 of the present invention, since the height is determined by the protruding portions 202 of the plate-shaped member 205, it is possible to form a flip chip mounting body 200 that has a constant and uniform gap between the semiconductor chip 206 and the circuit substrate 201. Therefore, the gap between the semiconductor chip 206 and the circuit substrate 201 is preliminarily determined, and by determining the length of the protruding portions 202 so as to provide the best distance, the connection terminals 204 and the electrode terminals 207 can be connected by using a predetermined amount of solder. Consequently, it becomes possible to achieve a reliable joined state in a stable manner, and also to realize a flip chip mounting body 200 with high reliability, which is free from warping and the like in the circuit substrate.

In embodiment 1 of the present invention, explanations have been given by using a plate-shaped member having four protruding portions; however, the present invention is not intended to be limited by this structure. For example, the shape of the protruding portions may be desirably designed as long as at least one opening section is formed therein. When the protruding portions are formed only on corner portions of the plate-shaped member, it is only necessary to provide at least three protruding portions so as to hold the plate-shaped member in a stable manner. Furthermore, when the protruding portions are formed on opposing side faces of the plate-shaped member, of course, only two of the protruding portions are required as long as the position is stably maintained in a stationary state.

In accordance with the flip chip mounting body of the present invention, the inner semiconductor chip can be protected by the plate-shaped member. Since it becomes possible to prevent the semiconductor chip from being rubbed or subjected to impacts upon transportation or the like, the reliability can be greatly improved. For example, in the case of a semiconductor chip having a thickness of about 30 μm, the use of the plate-shaped member having a thickness of about 100 μm ensures a sufficient strength required upon handling.

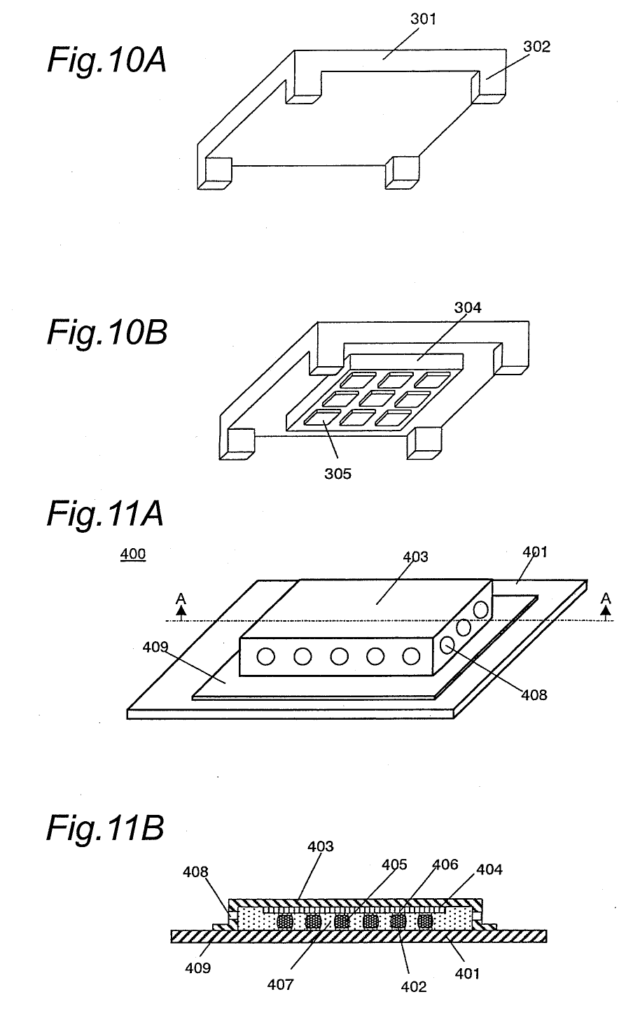

Referring to FIGS. 9(a) to 10(b), the following description will discuss a flip chip mounting body and a flip chip-mounting method in accordance with embodiment 1 of the present invention.

FIG. 9 are schematic cross-sectional views of processes, which explain the flip chip mounting body and the flip chip mounting method in accordance with embodiment 1 of the present invention. FIG. 10(a) is a perspective view that shows a plate-shaped member of FIG. 9(a) viewed diagonally from below, and FIG. 10(b) is a perspective view that shows a plate-shaped member of FIG. 9(b), viewed diagonally from below, to which a semiconductor chip has been attached.

First, as shown in FIG. 9(a), a plate-shaped member 301, suction-held by a vacuum suction device 303, is transported. As shown in FIG. 10(a), the plate-shaped member 301 is provided with four protruding portions 302 near its corner portions.

As shown in FIG. 9(b), a semiconductor chip 304 is secured to a predetermined position on the inside of the plate-shaped member 301 through a bonding or suction process. As shown in FIG. 10(b), a plurality of electrode terminals 305 are formed on the lower surface of the semiconductor chip 304. A resin composition 306 that has, for example, a sheet shape, and is mainly composed of solder powder, a convection additive and a resin, is bonded to the surface bearing the electrode terminals 305 of the semiconductor chip 304.

As shown in FIG. 9(c), the plate-shaped member 301 is moved to a predetermined position on the circuit substrate 307 by a transporting device (not shown). By using, for example, an image processing device, a positioning process between the connection terminals 308 of the circuit substrate 307 and the electrode terminals 305 of the semiconductor chip 304 is carried out so that the circuit substrate 307 and the plate-shaped member 301 are made in contact with each other through the protruding portions 302. Thus, the electrode terminals 305 of the semiconductor chip 304 and the connection terminals 308 of the circuit substrate 307 are aligned face to face with each other with a predetermined gap, by the protruding portions 302 of the plate-shaped member 301. Here, the predetermined gap refers to a gap adjusted in such a manner that, at least, the electrode terminals 305 of the semiconductor chip 304 and the connection terminals 308 of the circuit substrate 307 are not allowed to be made in contact with each other, but fused solder powder, which will be described later, is allowed to be invaded therein. For example, by taking the thickness of the semiconductor chip 304 and the like into consideration, the height of the protruding portions 302 is adjusted so that the distance between the electrode terminals 305 of the semiconductor chip 304 and the connection terminals 308 of the circuit substrate 307 is set in a range from about 10 μm to 50 μm. In addition to the connection terminals 308, the circuit substrate 307 may be provided with electrodes 309 used for forming pseudbumps and joining electrodes 310 that are joined to the protruding portions 302 of the plate-shaped member 301, which will be described later, if necessary.

The positioning process by the image processing device is carried out by recognizing, for example, the plate-shaped member 301 placed on the circuit substrate 307 and the joining electrodes 310 that join the plate-shaped member 301 to the circuit substrate 307. Needless to say, the resin composition 306 may be bonded onto the circuit substrate 307.

Next, as shown in FIG. 9(d), with the plate-shaped member 301 bearing the semiconductor chip 304 and the circuit substrate 307 being made in contact with each other by using the vacuum suction device 303, a heating process is carried out from the outside by using, for example, a heating device 311, such as an infrared ray heater, to a temperature, for example, from about 150° C. to 250° C., at which the solder powder in the resin composition 306 is fused.

The convection additive (not shown) in the resin composition 306 is boiled or evaporated into gases through the heating process, and the solder powder (not shown) is formed into fused solder powder. During a process in which the gases 312 are externally discharged between the protruding portions 302 of the plate-shaped member 301, fused solder powder in the resin composition 306 is moved through convections.

Furthermore, the fused solder powder, thus moved, is self-aggregated and allowed to grow in a gap between the electrode terminals 305 of the semiconductor chip 304 and the connection terminals 308 of the circuit substrate 307 that are aligned face to face with each other and have high wettability.

Thus, as shown in FIG. 9(e), solder layers 313, which electrically connects the electrode terminals 305 and the connection terminals 308, are formed, and after the resin in the resin composition 306 has been cured, the vacuum suction device 303 is detached so that a flip chip mounting body 200 is manufactured.

The fused solder powder is also self-aggregated on the electrode 310 on which pseudbumps are formed, and allowed to grow thereon to form pseudbumps 314. The formation of the pseudbumps 314 allows fused solder powder that has not been used for the formation of the solder layer 313 to be captured onto the electrode 310 forming the pseudbumps and prevented from flowing out.

In the case when no solder powder is scattered or no problems are raised even if solder powder is scattered, it is not necessarily required to prepare the electrode 310 forming the pseudbumps.

In embodiment 1, for example, a structure in which the solder layer 313 is formed with the circuit substrate 307 and the plate-shaped member 301 are being held by the vacuum suction device 303 has been explained; however, the present invention is not intended to be limited by this structure. For example, after securing the protruding portions 302 of the plate-shaped member 301 have been preliminarily secured to the circuit substrate 307 through press bonding or ultrasonic wave joining, the vacuum suction device 303 is removed therefrom, and the processes succeeding the heating process may be carried out. For example, the manufacturing processes are automatically carried out by using a reflow device or the like.

In embodiment 1, after the sheet-shaped resin composition has been bonded to the semiconductor chip or the circuit substrate, the heating process is carried out; however, the present invention is not intended to be limited by this method. For example, after the protruding portions 302 of the plate-shaped member 301 have been bonded to the circuit substrate 307, a paste-state resin composition may be injected between the semiconductor chip 304 and the circuit substrate 307 while these are being maintained with a predetermined gap, and subjected to a heating process.

With this arrangement, since a number of intermediate boards of the flip chip mounting bodies are manufactured, with the circuit substrates and the plate-shaped members being secured thereto, and subjected to a heating process at one time, the productivity can be further improved.

Another structure may be proposed in which: a solder film is preliminarily formed on the protruding portions 302 of a plate-shaped member 301 having protruding portions 302 which are made from metal or at least the tips of which are coated with metal, as well as on the electrodes 310 of the circuit substrate 307, and upon completion of the heating process, the circuit substrate 307 and the plate-shaped member 301 are joined and secured to each other through solder. The solder film may be formed by using a material having a high melting point of, for example, 300° C., which is higher than the melting point of solder powder in the resin composition 306, and the solder film is locally fused by using, for example, a laser beam so that the circuit substrate 307 and the protruding portions 302 are joined to each other through solder, and the succeeding processes may be carried out. In this case, with the vacuum suction device having been removed therefrom, the succeeding heating treatment can be carried out. However, upon heating the resin composition 306, the succeeding heating treatment needs to be carried out, for example, at a temperature lower than the melting point (300° C.) of the solder film so that the protruding portions 302 and the electrodes 310 of the circuit substrate 307 are not separated from each other.

In the case when the melting point of the solder film and the melting point of the solder powder in the resin composition 306 are virtually in the same level, upon completion of the heating process, the plate-shaped member 301 and the circuit substrate 307 are joined to each other. With this arrangement, it becomes possible to positively secure the circuit substrate to the plate-shaped member, without an increase in the number of processes.

For convenience of explanation, embodiment 1 has exemplified a structure in which a gap is made between the semiconductor chip and the protruding portions of the plate-shaped member; however, a structure in which the semiconductor chip is placed up to the limit of the inner size of the protruding portions. This arrangement can achieve further miniaturization.

Embodiment 1 has exemplified a sheet-shaped resin as a resin composition 306; however, the present invention is not intended to be limited by this structure. Needless to say, for example, a paste-state or jelly-state resin may be applied thereto.

As described above, in embodiment 1 of the present invention, it becomes possible to achieve a flip chip mounting process for a semiconductor chip by using a very simple and positive method.

The semiconductor chip can be protected by the plate-shaped member, and since the occurrence of defective connection due to an impact or the like caused upon transportation can be prevented, it becomes possible to achieve a flip chip mounting body that is superior in reliability and productivity.

### EMBODIMENT 2

FIG. 11(a) is a perspective view that shows a flip chip mounting body in accordance with embodiment 2 of the present invention, and FIG. 11(b) is a cross-sectional view taken along line A-A of FIG. 11(a).

In FIG. 11, the flip chip mounting body 400 of embodiment 2 of the present invention has a structure in which a plurality of connection terminals 402 formed on a circuit substrate 401 and a plurality of electrode terminals 406 of a semiconductor chip 404, placed face to face with each other, are electrically connected to each other through a solder layer 405. A box-shaped member 403, bonded to the opposite side to the electrode terminals 406 of the semiconductor chip 404, is formed in a manner so as to cover the semiconductor chip 404. The box-shaped member 403 has a flange 409 placed on the periphery thereof and a plurality of holes 408 capable of ventilating outer and inner sides, and is joined to the circuit substrate 401 through the flange 409 by using, for example, a resin bonding agent. In the above description, the joining process by the use of a resin bonding agent has been explained; however, the box-shaped member 403 may be attached to the circuit substrate 401 by using various methods such as press bonding, soldering and ultrasonic wave joining. The box-shaped member 403 may be made of metal or resin coated with metal. A conductive resin in which, for example, carbon is mixed may be used as a box-shaped member 403 so as to protect the semiconductor chip 404 from static electricity. Furthermore, needless to say, a conductive resin in which, for example, nickel is mixed may be used as a box-shaped member 403 so as to shield electromagnetic waves.

With respect to the circuit substrate 401 and the box-shaped member 403, at least the semiconductor chip 404 and the circuit substrate 401 are secured by the resin 407 surrounding the periphery thereof, together with the solder layer 405 that electrically connects the connection terminals 402 to the electrode terminals 406. The resin 407, used for securing the box-shaped member 403, may be the same material as the resin in the resin composition, or a different material may be used. In this case, after forming the solder layer 405, the resin composition is once removed, and another resin is again injected from the hole 408 of the box-shaped member 403 to be filled therein.

In embodiment 2 of the present invention, an electrode, used in embodiment 1 so as to prevent solder powder from scattering, is not placed on the periphery of a portion to which the semiconductor chip 404 of the circuit substrate 401 is joined. The reason for this is because the flow of solder powder is blocked by the flange 409, and thereby prevented from scattering to outside. Needless to say, in the case when a box-shaped member without the flange 409 or a box-shaped member with a large hole is used, of course, an electrode, used for preventing solder powder from scattering, may be placed to form pseudbumps, in the same manner as embodiment 1.

In accordance with embodiment 2 of the present invention, it is possible to provide a flip chip mounting body with high reliability, which has a simple structure, and is free from short-circuiting due to a flow of solder powder to the outside and scattering thereof.

Since a shape completely enclosing the semiconductor chip by the box-shaped member is prepared, the mechanical strength against deformation and the like can be improved, and by forming the structure using a conductive material or the like, it becomes possible to reduce radiation of electromagnetic waves and the like.

The gap between the semiconductor chip 404 and the circuit substrate 401 can be maintained at a constant value by adjusting the height of the side faces of the box-shaped member 403; therefore, it is possible to ensure the uniformity of the height and the size of the solder layer 405 when the semiconductor chip 404 is mounted. For this reason, the gap between the semiconductor chip 404 and the circuit substrate 401 is preliminarily determined, and by determining the height of the side faces of the box-shaped member 403 so as to provide the best distance, the connection terminals 402 and the electrode terminals 406 can be connected by using a predetermined amount of solder; thus, it becomes possible to realize a flip chip mounting body 400 with high reliability, which has a reliable joined state in an extremely stable manner.

Embodiment 2 of the present invention has exemplified a structure in which the hole 408 of the box-shaped member 403 is comparatively large and the number thereof provided is also small; however, the number and size of the holes 408 are optional, and, of course, various modifications can be made therein.

In accordance with the flip chip mounting body of the present invention, the inner semiconductor chip can be protected by the box-shaped member. Since it becomes possible to prevent the semiconductor chip from being rubbed or subjected to impacts upon transportation, the reliability can be greatly improved.

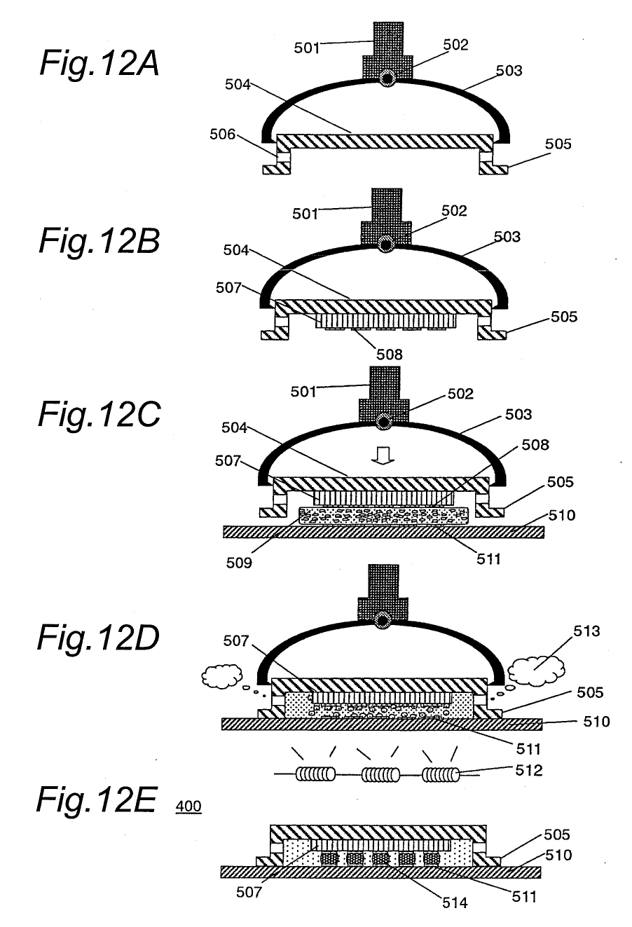

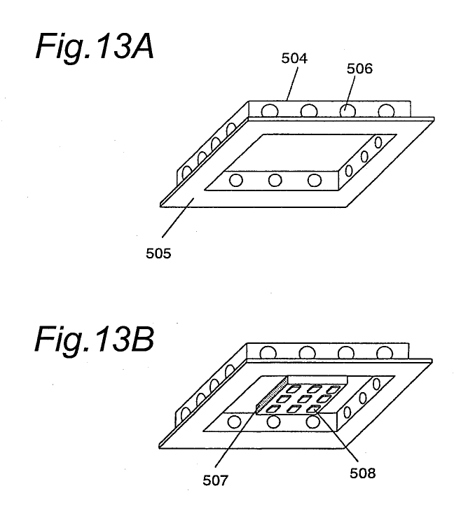

Referring to FIGS. 12 to 13, the following description will discuss a flip chip mounting body and a flip chip mounting method in accordance with embodiment 2 of the present invention.

FIG. 12 is schematic cross-sectional views of processes, which explain the flip chip mounting body and the flip chip mounting method of embodiment 2 of the present invention. FIG. 12(a) is a perspective view that shows a box-shaped member of FIG. 12(a) viewed diagonally from below, and FIG. 13(b) is a perspective view that shows a box-shaped member of FIG. 12(b), viewed diagonally from below, to which a semiconductor chip has been attached.

First, as shown in FIG. 12(a), a box-shaped member 504 preliminarily formed is held by a bite arm 503, and transported. A transporting device 501 is provided with the bite arm 503 used for pinching a transporting object at its tip and a hinge 502 that opens and closes the bite arm 503 and is rotatable. As shown in FIG. 13(a), the box-shaped member 504 is provided with a plurality of holes 506 that allow ventilation on its side faces and a flange 505 formed around the opening section of its end face.

As shown in FIG. 12(b), a semiconductor chip 507 is bonded or secured to a predetermined position on the inside of the box-shaped member 504. As shown in FIG. 13(b), a plurality of electrode terminals 508 are formed on the lower surface of the semiconductor chip 507.

As shown in FIG. 12(c), a resin composition 509, mainly composed of solder powder, a convection additive and a resin, is preliminarily applied to the circuit substrate 510, and the box-shaped member 504 with the semiconductor chip 507 being bonded thereto is transported above a predetermined position by using the transporting device 501. By using, for example, an image processing device or the like, a positioning process between the connection terminals 511 of the circuit substrate 510 and the electrode terminals 508 of the semiconductor chip 507 is carried out so that the circuit substrate 510 and the flange 505 of the box-shaped member 504 are made in contact with each other. Thus, the electrode terminals 508 of the semiconductor chip 507 and the connection terminals 511 of the circuit substrate 510 are aligned face to face with each other with a predetermined gap by the flange 505 and the height of the side faces of the box-shaped member 504. The predetermined gap refers to a gap that, at least, does not allow the electrode terminals 508 of the semiconductor chip 507 and the connection terminals 511 of the circuit substrate 510 to be made in contact with each other, and allows melted solder powder, which will be described later, to be invaded therein.

The positioning process by the image processing device is carried out by recognizing, for example, a marker (not shown) formed on the circuit substrate 510 and the flange 505 of the box-shaped member 504.

As shown in FIG. 12(d), with the box-shaped member 504 bearing the semiconductor chip 507 and the circuit substrate 510 being made in contact with each other through the transporting device 501, a heating process is carried out from the outside by using, for example, a heating device 512, such as an infrared ray heater, to a temperature, for example, from about 150° C. to 250° C., at which the solder powder in the resin composition 306 is allowed to melt.

The convection additive (not shown) in the resin composition 509 is boiled or evaporated into gases through the heating process, and the solder powder (not shown) is formed into fused solder powder. During a process in which the gases 513 are discharged to the outside through the holes 408 of the box-shaped member 504, fused solder powder in the resin composition 509 is shifted through convections.

The fused solder powder, thus moved, is self-aggregated onto the electrode terminals 508 of the semiconductor chip 507 and the connection terminals 511 of the circuit substrate 510 that are aligned face to face with each other and have high wettability, and allowed to grow so that an electrical connection is made between the electrode terminals 508 and the connecting terminals 511.

Thus, as shown in FIG. 12(e), a solder layer 514, which electrically connects the electrode terminals 508 and the connection terminals 511, is formed, and after the resin in the resin composition 509 has been cured, the transporting device 501 is detached so that a flip chip mounting body 400 is manufactured.

At this time, the resin in the resin composition 509 is softened to join the semiconductor chip 507 and the circuit substrate 510 to each other, and also to be injected into a gap between the flange 505 of the box-shaped member 504 and the circuit substrate 510 so that the box-shaped member 504 and the circuit substrate 510 are joined and secured to each other.

In embodiment 2 of the present invention, no electrode to be used for preventing solder powder from scattering is provided; however, this electrode may of course be formed.

In embodiment 2 of the present invention, the box-shaped member 504 having the flange 505 attached thereto is used; however, the flange 505 may be omitted, and, of course, a flange 505, bent not outward, but inward in the box-shaped member 504, may be used.

As described above, in accordance with embodiment 2 of the present invention, a flip chip mounting process of a semiconductor chip can be carried out by using a very simple and positive method.

The semiconductor chip can be protected by the box-shaped member, and since the occurrence of defective connection due to an impact or the like caused upon transportation can be prevented, it becomes possible to achieve a flip chip mounting body that is superior in reliability and productivity.

In embodiment 2 of the present invention, comparatively large holes 506 are shown; however, a number of small holes may be formed. In this case, it is also expected that the holes 506 are finally plugged by the resin in the resin composition 509. As a result, since the semiconductor chip 507 is completely shielded from outside air, no moisture or the like is invaded therein, making it possible to improve the service life and reliability of the semiconductor chip and the connecting portion such as the solder layer.

Although the invention has been described with reference to respective embodiments thereof, the invention is not intended to be limited by these descriptions, and various modifications can be made therein. For example, with respect to the resin containing the solder powder and the convection additive agent, an explanation has been given by exemplifying a thermosetting resin; however, for example, a photo-curable resin having flowability at a temperature higher than the melting point of the solder powder or a combination-type resin of these resins may be used.

In the respective embodiments of the present invention, a structure having a single semiconductor chip has been exemplified; however, a plurality of semiconductor chips may be placed on the circuit substrate simultaneously, and the respective processes may be carried out.

In the respective embodiments of the present invention, explanations have been given by exemplifying a shape in which the plate-shaped member or the box-shaped member is bent at right angles; however, not limited by this shape, for example, a tapered shape may be used. With this arrangement, the machining processes of the plate-shaped member and the box-shaped member are made easier, making it possible to cut costs.

In the respective embodiments of the present invention, with respect to the resin in the resin composition, a resin including as its main agent any one of the resins, selected from epoxy resin, unsaturated polyester resin, polybutadiene resin, polyimide resin, polyamide resin or cyanate resin, may be used.

In the respective embodiments of the present invention, with respect to the convection additive, middle-boiling-point solvents or high-boiling-point solvents, which include decomposition-type materials, such as sodium hydrogen carbonate, ammonium methaborate, aluminum hydroxide, dorsonite and barium methaborate, and boiling evaporation-type materials, such as butyl carbitol, flux, isobutyl alcohol, xylene, isopentyl alcohol, butyl acetate, tetrachloroethylene, methylisobutylketone, ethyl carbitol, butyl carbitol and ethylene glycol, may be used.

### INDUSTRIAL APPLICABILITY

The present invention is applicable to a flip chip mounting process for the next generation semiconductor chip in which narrower pitches have been achieved, and is also effectively used in the field in which flip chip mounting that is superior in the productivity and reliability is demanded.

1-35. (canceled)

36. A method of manufacturing an electronic-part mounting body including an electronic part and a circuit substrate on which the electronic part is mounted, wherein the electronic part comprises a plurality of electrode terminals formed on the surface of the electronic part that faces the circuit substrate; the circuit substrate is provided with electrode terminals formed thereon in association with the respective plurality of the electrode terminals; and a plurality of spacer members are placed on an area other than the electrode terminals of the connected circuit substrate and the electrode terminal portions of the electronic part, and wherein the electrode terminals of the circuit substrate and the electrode terminals of the electronic part are electrically connected to each other by solder bumps that are formed in a self-aggregating manner, the method comprising:
(a) preparing an electronic part having a surface on which electrode terminals are arranged;
(b) preparing a circuit substrate having a surface on which electrode terminals, arranged in association with the electrode terminals of the electronic part;
(c) forming a plurality of spacers at an area other than the electronic terminal portion on the surface bearing the electrode terminals, on at least either one of the electronic part and the circuit substrate;
(d) applying a solder resin paste, containing a resin, as well as solder powder and a convection additive that is allowed to boil upon heating the resin contained in the resin, to at least either one of the faces of the electronic part and the circuit substrate;
(e) placing the electronic part on the circuit substrate with the solder resin paste being sandwiched in between; and
(f) heating the solder resin paste to allow the convection additive to boil, thereby allowing the fused solder powder in the resin to flow in the resin and to be self-aggregated and allowed to grow so that by the resin, the electrode terminals possessed by the electronic part and electrode terminals formed on the circuit substrate in association with the electrode terminals are electrically connected,
wherein a predetermined gap is formed between the electrode terminals arranged on the electronic part and the electrode terminals arranged on the circuit substrate face in association therewith, by the spacers prepared in the above-mentioned step.

37. A method of manufacturing an electronic-part mounting body including an electronic part and a circuit substrate on which the electronic part is mounted, wherein the electronic part comprises a plurality of electrode terminals formed on the surface of the electronic part that faces the circuit substrate; the circuit substrate is provided with electrode terminals formed thereon in association with the respective plurality of the electrode terminals; and a plurality of spacer members are placed on an area other than the electrode terminals of the connected circuit substrate and the electrode terminal portions of the electronic part, and wherein the electrode terminals of the circuit substrate and the electrode terminals of the electronic part are electrically connected to each other by solder bumps that are formed in a self-aggregating manner, the method comprising:
(a) preparing an electronic part having a surface on which electrode terminals are arranged;
(b) preparing a circuit substrate having a surface on which electrode terminals, arranged in association with the electrode terminals of the electronic part;
(c) forming a plurality of spacers at an area other than the electronic terminal portion on the surface bearing the electrode terminals, on at least either one of the electronic part and the circuit substrate;
(d) arranging the electronic part on the circuit substrate;
(e) injecting a solder resin paste, containing a resin as well as solder powder and a convection additive that is allowed to boil upon heating the resin contained in the resin, into a space formed between the electronic part and the circuit substrate; and
(f) heating the solder resin paste to allow the convection additive to boil, thereby allowing the fused solder powder in the resin to flow in the resin and to be self-aggregated and allowed to grow so that by the resin, the electrode terminals possessed by the electronic part and electrode terminals formed on the circuit substrate in association with the electrode terminals are electrically connected,
wherein a predetermined gap is formed between the electrode terminals arranged on the electronic part and the electrode terminals arranged on the circuit substrate face in association therewith, by the spacers prepared in the above-mentioned step.

38. The method of manufacturing an electronic-part mounting body according to claim 36, wherein in the step of arranging the electronic part on the circuit substrate, the electronic part is bonded to and maintained on the circuit substrate by using the spacers.

39. A flip chip mounting body comprising:
a circuit substrate having a plurality of connection terminals;
a semiconductor chip having a plurality of electrode terminals that are placed face to face with the connection terminals; and
a plate-shaped member in which the semiconductor chip is positioned on the inner side thereof and bonded thereto, and which has at least two protruding portions placed on end portions thereof,
wherein the connection terminals of the circuit substrate and the electrode terminals of the semiconductor chip are electrically connected to each other by using a solder layer, with at least the circuit substrate and the semiconductor chip being fixed by a resin.

40. The flip chip mounting body according to claim 39, wherein an electrode is formed in a manner so as to surround the connection terminals of the circuit substrate, with a pseudbump being formed on the electrode.

41. The flip chip mounting body according to claim 40, wherein the electrodes are formed in a scattered manner.

42. The flip chip mounting body according to claim 39, wherein at least the tip of each protruding portion of the plate-shaped member is made from metal or a resin coated with metal, and has wettability to solder.

43. The flip chip mounting body according to claim 39, wherein the circuit substrate and the protruding portions of the plate-shaped member are joined to each other through press bonding or ultrasonic wave joining.

44. The flip chip mounting body according to claim 39, wherein the circuit substrate and the plate-shaped member are joined to each other by the resin of the resin composition.

45. A flip chip mounting method, which places a semiconductor chip having a plurality of electrode terminals so as to face a circuit substrate having a plurality of connection terminals so that the connection terminals of the circuit substrate and the electrode terminals of the semiconductor chip are electrically connected to each other, comprising:
positioning the semiconductor chip with respect to a plate-shaped member having at least two protruding portions placed on end portions thereof, and bonding the semiconductor chip thereto;
applying or adhering a resin composition mainly composed of solder powder, a convection additive and a resin to the circuit substrate or the semiconductor chip;
positioning the protruding portions of the plate-shaped member to which the semiconductor chip has been bonded so as to be placed on the circuit substrate, and securing the circuit substrate and the semiconductor chip to each other by the protruding portions with a specified gap;
heating the resin composition to a temperature at which the solder powder is fused so that a gas is generated through boiling or decomposition of the convection additive; and
allowing the fused solder powder to flow in the resin composition, during a process in which the gas is allowed to flow and discharged between the protruding portions of the plate member, and to be self-aggregated and allowed to grow so that the connection terminals and the electrode terminals are electrically connected to each other.

46. The flip chip mounting method according to claim 45, wherein the resin composition is made of a plate-shaped resin, a sheet-shaped resin or a paste-state resin, and is allowed to adhere to the circuit substrate or the semiconductor chip.

47. The flip chip mounting method according to claim 45, wherein, in the step of securing the protruding portions of the plate-shaped member to the circuit substrate, the protruding portions thereof are secured on the circuit substrate through solder preliminarily formed on the circuit substrate.

48. The flip chip mounting method according to claim 45, wherein, in the step of securing the protruding portions of the plate-shaped member to the circuit substrate, the protruding portions of the plate-shaped member are joined to the circuit substrate through press bonding or ultrasonic wave joining.

49. A flip chip mounting body comprising:
a circuit substrate having a plurality of connection terminals;
a semiconductor chip having a plurality of electrode terminals that are placed face to face with the connection terminals; and
a box-shaped member in which the semiconductor chip is positioned on the inner side thereof and bonded thereto, and which has a hole that allows ventilation, and is opened at least in one direction only on the side face portion to which no semiconductor chip is bonded,
wherein the connection terminals of the circuit substrate and the electrode terminals of the semiconductor chip are electrically connected to each other by using a solder layer, with at least the circuit substrate and the semiconductor chip being secured to each other by a resin.

50. The flip chip mounting body according to claim 49, wherein the box-shaped member covers the semiconductor chip and is formed into a box shape with the peripheral edge sticking out to form a flange placed on the peripheral portion of the opening of the box-shaped member.

51. The flip chip mounting body according to claim 49, wherein an electrode is formed in a manner so as to surround the connection terminals of the circuit substrate, with pseudbumps being formed on the electrode.

52. The flip chip mounting body according to claim 51, wherein the electrodes are formed in a scattered manner.

53. The flip chip mounting body according to claim 49, wherein the box-shaped member is made of metal or resin coated with metal, and has wettability to solder.

54. The flip chip mounting body according to claim 49, wherein the circuit substrate and the box-shaped member are joined to each other through press bonding or ultrasonic wave joining.

55. The flip chip mounting body according to claim 49, wherein the circuit substrate and the box-shaped member are joined to each other by the resin of the resin composition.

56. A flip chip mounting method, which places a semiconductor chip having a plurality of electrode terminals so as to face a circuit substrate having a plurality of connection terminals so that the connection terminals of the circuit substrate and the electrode terminals of the semiconductor chip are electrically connected to each other, comprising:
positioning the semiconductor chip inside a box-shaped member that has a hole that allows ventilation, and is opened at least in one direction, and bonding the semiconductor chip thereto;
applying or adhering a resin composition mainly composed of solder powder, a convection additive and a resin to the circuit substrate or the semiconductor chip;
positioning the box-shaped member to which the semiconductor chip has been bonded so as to be placed on the circuit substrate, as well as securing the circuit substrate and the semiconductor chip to each other, with a specified gap, by the side edge portion on the opening side of the box-shaped member;
heating the resin composition to a temperature at which the solder powder is fused so that a gas is generated through boiling or decomposition of the convection additive; and
allowing the fused solder powder to flow in the resin composition, during a process in which the gas is allowed to flow and discharged through the hole of the box-shaped member, and to be self-aggregated and allowed to grow so that the connection terminals and the electrode terminals are electrically connected to each other.

57. The flip chip mounting method according to claim 56, wherein the resin composition is made of a plate-shaped resin, a sheet-shaped resin or a paste-state resin, and is allowed to adhere to the circuit substrate or the semiconductor chip.

58. The flip chip mounting method according to claim 56, wherein, in the step of securing the side edge portion on the opening side of the box-shaped member to the circuit substrate, the side edge portion thereof is secured on the circuit substrate through solder preliminarily formed on the circuit substrate.

59. The flip chip mounting method according to claim 56, wherein, in the step of securing the side edge portion on the opening side of the box-shaped member to the circuit substrate, the box-shaped member is joined to the circuit substrate through press bonding or ultrasonic wave joining.

60. The flip chip mounting method according to claim 56, wherein, in the step of securing the side edge portion on the opening side of the box-shaped member to the circuit substrate, with the resin composition being interposed between the circuit substrate and the semiconductor chip, the box-shaped member is pressed until the side edge portion on the opening side thereof has been made in contact with the circuit substrate.
